(19) United States
(12) Patent Application Publication
(10) Pub. No.: US 2022/0403500 A1
(43) Pub. Date: Dec. 22, 2022

(54) STRUCTURAL COATING AND PREPARATION METHOD AND USE THEREOF

(71) Applicant: Lanzhou Institute of Chemical Physics, Chinese Academy of Sciences, Lanzhou (CN)

(72) Inventors: Peng Wang, Lanzhou (CN); Li Qiao, Lanzhou (CN); Hong Zhang, Lanzhou (CN); Xiaogang Bai, Lanzhou (CN)

(21) Appl. No.: 17/528,694

(22) Filed: Nov. 17, 2021

(30) Foreign Application Priority Data
Jun. 22, 2021 (CN) 202110689754.2

(51) Int. Cl. C23C 14/18; H05B 3/12; C23C 14/35

(52) U.S. Cl. CPC C23C 14/18; H05B 3/12; C23C 14/352; H05B 2203/017; H05B 2203/013

(57) ABSTRACT

The present disclosure relates to a structural coating and preparation method and use thereof. The structural coating provided in the present disclosure includes a titanium transition layer and platinum-hafnium composite structure layers laminated in sequence on a surface of a substrate; the number of the platinum-hafnium composite structure layer is ≥3; the platinum-hafnium composite structure layer includes a hafnium layer and a platinum layer laminated in sequence.

### CROSS REFERENCE TO RELATED APPLICATION(S)

This patent application claims the benefit and priority of Chinese Patent Application No. 202110689754.2 filed on Jun. 22, 2021, the disclosure of which is incorporated by reference herein in its entirety as part of the present application.

### TECHNICAL FIELD

The present disclosure relates to the technical field of coating resistance materials, and in particular to a structural coating and preparation method and use thereof.

### BACKGROUND ART

Electric heating elements have been applied in many occasions as micro-electric system heating sources, micro-simulation reactors, thermal cutting devices and the like. The electric heating elements are generally resistances made of metal coating materials, and are implemented by means of such as resistance heating. Therefore, the resistivity of the coating is a key parameter affecting the device performance, and is closely related to the preparation process, size and material of the coating. In particular, when reaching a micro-nano level in structure, the resistivity of material is different from that of a conventional size. Thus, it is fundamental research to study the resistance materials and coating characteristics of electric heating elements.

Currently, the commonly used coating resistance materials mainly include such as platinum, titanium, chromium and nickel-chromium alloys. Based on the advantages of high-temperature resistivity stability, oxidation resistance and corrosion resistance, the metal of platinum has been used in most coating resistances as a heating source. However, due to the inherent inertness of the platinum metal, the pure platinum coating has a poor adhesion to semiconductor and dielectric substrates. Therefore, researchers usually insert a layer of titanium coating between the platinum coating and the substrate as an adhesion promoter. Although the introduction of titanium improves the bonding of the coating, the high affinity of titanium to oxygen and the wettability of the metal in the recrystallization process at high temperatures result in the formation of a raised hillock-like structure on platinum coating, which in turn causes the raised hillock-like structure of the coating. This results in local discontinuity of the coating, so that the performance of the platinum coating electric heating elements such as temperature sensors or heaters degrades in the temperature range of 500 to 900° C., eventually leading to the function failure of micro devices.

### SUMMARY

An object of the present disclosure is to provide a structural coating and a preparation method and use thereof. The resistance of the structural coating has good high-temperature stability.

In order to achieve the above object, the present disclosure provides the technical solution as follows.

The present disclosure provides a structural coating, including a titanium transition layer and platinum-hafnium composite structure layers laminated sequentially on a surface of a substrate; the number of the platinum-hafnium composite structure layer is ≥3;

the platinum-hafnium composite structure layer includes a hafnium layer and a platinum layer laminated in sequence.

In some embodiments, the structural coating has a total thickness of 900 nm to 2000 nm.

In some embodiments, the titanium transition layer has a thickness of 140 nm to 300 nm.

In some embodiments, a thickness ratio of the platinum layer to the hafnium layer is (20-22):(7-10).

The present disclosure further provides a method for preparing the structural coating described in the above technical solution, including:

preparing a titanium transition layer and platinum-hafnium composite structure layers sequentially on a surface of a substrate to obtain the structural coating;

a process of preparing the platinum-hafnium composite structure layers includes depositing a hafnium layer and a platinum layer sequentially and repeatedly on a surface of the titanium transition layer, and the deposition of the hafnium layer and the platinum layer is repeated for ≥3 times.

In some embodiments, conditions for depositing the titanium transition layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 14 min to 16 min; a power of Ti target is 220 W to 250 W.

In some embodiments, conditions for depositing the hafnium layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 4.5 min to 5.5 min; a power of hafnium target is 180 W to 185 W.

In some embodiments, conditions for depositing the platinum layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 7 min to 8 min; a power of platinum target is 180 W to 185 W.

The present disclosure further provides use of the structural coating described in the above technical solution or the structural coating prepared by the method described in the above technical solution in an electric heating element.

The present disclosure provides a structural coating, including a titanium transition layer and platinum-hafnium composite structure layers laminated sequentially on a surface of a substrate, wherein the number of the platinum-hafnium composite structure layer is ≥3, and the platinum-hafnium composite structure layer includes a hafnium layer and a platinum layer laminated in sequence. In the present disclosure, the relatively high melting point and low resistivity of hafnium are utilized, and the hafnium layer is arranged between the titanium transition layer and the platinum layer as a composite phase of the platinum layer, which effectively improves the temperature for recrystallization of the structural coating during heating, and inhibits the diffusion of the titanium transition layer to the metal resistance layer (the platinum layer) at high temperatures; moreover, by arranging the number of the platinum-hafnium composite structure layer to be ≥3, the interface strengthening effect is increased, the diffusion rate between different metals is reduced, and the electrical stability of platinum resistance layer is enhanced. Based on the above, the structural coating with high thermal stability is finally obtained.

### BRIEF DESCRIPTION OF THE DRAWINGS

FIG. 1 is a schematic view of the cross-section of the structural coating in Example 1;

FIG. 2 is a SEM image of the cross-section of the structural coating in Example 1,

FIG. 3 is a Rutherford backscattering spectrum of the structural coating after heat treatment in Example 1;

FIG. 4 is a resistivity change curve of the structural coatings after heat treatment in Example 1 and Comparative Examples 1-3;

FIG. 5 is a schematic view of the cross-section of the structural coating in Comparative Example 1;

FIG. 6 is a SEM image of the cross-section of the structural coating in Comparative Example 1;

FIG. 7 is a Rutherford backscattering spectrum of the structural coating after heat treatment in Comparative Example 1;

FIG. 8 is a schematic view of the cross-section of the structural coating in Comparative Example 2;

FIG. 9 is a SEM image of the cross-section of the structural coating in Comparative Example 2;

FIG. 10 is a Rutherford backscattering spectrum of the structural coating after heat treatment in Comparative Example 2;

FIG. 11 is a schematic view of the cross-section of the structural coating in Comparative Example 3;

FIG. 12 is a SEM image of the cross-section of the structural coating in Comparative Example 3; and

FIG. 13 is a Rutherford backscattering spectrum of the structural coating after heat treatment in Comparative Example 3.

### DETAILED DESCRIPTION OF THE EMBODIMENTS

The present disclosure provides a structural coating, including a titanium transition layer and platinum-hafnium composite structure layers laminated in sequence on a surface of a substrate; the number of the platinum-hafnium composite structure layer is ≥3;

the platinum-hafnium composite structure layer includes a hafnium layer and a platinum layer laminated in sequence.

In the present disclosure, the structural coating has a total thickness preferably of 900 nm to 2000 nm, more preferably of 1000 nm to 1800 nm, and most preferably of 1300 nm to 1600 nm.

In the present disclosure, when the structural coating has a thickness greater than 2000 nm, the adhesion between the coating and the substrate will be weakened due to the excessive thickness of the coating, and the mechanical properties of the coating will be further reduced; when the structural coating has a thickness less than 900 nm, the conductivity of the coating is weakened, thereby reducing the practicability of the components based on the structural coating, and even leading to the failure of the resistance components.

The present disclosure has no special limitation on the material of the substrate, and those well known to the skilled in the art may be used. In a specific embodiment of the present disclosure, the substrate is specifically a silicon nitride substrate.

In the present disclosure, the structural coating includes a titanium transition layer, and the titanium transition layer has a thickness preferably of 140 nm to 300 nm, more preferably of 180 nm to 260 nm, and most preferably of 200 nm to 230 nm.

In the present disclosure, the titanium transition layer plays a role of increasing the bonding between the platinum resistance layer and the substrate, and the thickness of the titanium transition layer is controlled within the above range to enhance the bonding between the coating and the substrate, while weakening the influence of the transition layer on the electrical properties of the resistance layer as much as possible.

In the present disclosure, the number of the platinum-hafnium composite structure layer is ≥3, and is preferably 3-6.

In the present disclosure, if the number of the platinum-hafnium composite structure layer is too large, the thickness of the single layers will be reduced, and thus the blocking effect of the hafnium element on the thermal diffusion is not obvious, thereby retaining a mass diffusion of the titanium transition layer into the platinum resistance layer, which affects the application of the structural coating in the resistance components; if the number of the platinum-hafnium composite structure layer is too small, the multi-layer interface effect is not obvious, thereby retaining the diffusion of different metals between layers, which affects the high thermal stability and practical application of the resistance coating.

In the present disclosure, the platinum-hafnium composite structure layer preferably includes a hafnium layer and a platinum layer laminated in sequence. In the present disclosure, the thickness ratio of the platinum layer to the hafnium layer is preferably (20-22):(7-10), and more preferably (20.5-21.5):(8-9).

In the present disclosure, when the thickness ratio of the platinum layer to the hafnium layer is too large, the blocking effect of the hafnium layer is not obvious, and thus a mass diffusion of the titanium transition layer to the platinum resistance layer is retained, which affects the application of the structural coating in resistance components; when the thickness ratio of the platinum layer to the hafnium layer is too small, the effect of the platinum layer as the conductive layer will be weakened, thereby reducing the practicability of the components based on the structural coating, and even leading to the failure of the resistance components.

The present disclosure further provides a method for preparing the structural coating described in the above technical solution, comprising:

preparing a titanium transition layer and platinum-hafnium composite structure layers sequentially on a surface of a substrate to obtain the structural coating;

a process of preparing the platinum-hafnium composite structure layer includes depositing a hafnium layer and a platinum layer sequentially and repeatedly on a surface of the titanium transition layer, and the deposition of the hafnium layer and the platinum layer is repeated for ≥3 times.

In the present disclosure, unless otherwise specified, all the raw materials for preparation are commercially available products well known to those skilled in the art.

The present disclosure has no special limitation on the material type of the substrate, and those well known to the skilled in the art may be used. In a specific embodiment of the present disclosure, the substrate is specifically a silicon nitride substrate.

In the present disclosure, the method for preparing the titanium transition layer is preferably deposition. Before the deposition, the present disclosure further preferably includes pretreatment to the substrate. The pretreatment preferably includes etching the surface of the substrate with argon plasma for 5 min to 15 min, followed by removing the natural oxidation and impurity contamination layers from the substrate surface with a bias voltage of −500 V to −600 V.

In the present disclosure, the method for the deposition is preferably magnetron sputtering physical vapor deposition, electron beam evaporation coating or chemical vapor deposition, and more preferably magnetron sputtering physical vapor deposition.

When the deposition method is magnetron sputtering physical vapor deposition, the purity of the titanium target for depositing the titanium transition layer is preferably 99.995%, and the diameter of the titanium target is preferably 75 mm. In the present disclosure, the conditions for depositing the titanium transition layer are preferably as follows: the flow rate of argon gas is preferably 39 sccm to 41 sccm, and more preferably 40 sccm; the working pressure for argon plasma is preferably 6.0×10⁻¹ Pa to 8.0×10⁻¹ Pa, more preferably 6.5×10⁻¹ Pa to 7.5×10⁻¹ Pa, and most preferably 6.8×10⁻¹ Pa to 7.3×10⁻¹ Pa; the temperature is preferably 120° C. to 160° C., more preferably 130° C. to 150° C., and most preferably 135° C. to 145° C.; the time duration is preferably 14 min to 16 min, more preferably 15 min, and most preferably 18 min to 22 min; the power of Ti target is preferably 220 W to 250 W, more preferably 225 W to 245 W, and most preferably 230 W to 240 W.

When the deposition method is magnetron sputtering physical vapor deposition, the purity of the hafnium target for depositing the hafnium layer is preferably 99.99%, and the diameter of the hafnium target is preferably 75 mm. In the present disclosure, the conditions for depositing the hafnium layer are preferably as follows: the flow rate of argon gas is preferably 39 sccm to 41 sccm, and more preferably 40 sccm; the working pressure for argon plasma is preferably 6.0×10⁻¹ Pa to 8.0×10⁻¹ Pa, more preferably 6.5×10⁻¹ Pa to 7.5×10⁻¹ Pa, and most preferably 6.8×10⁻¹ Pa to 7.3×10⁻¹ Pa; the temperature is preferably 120° C. to 160° C., more preferably 130° C. to 150° C., and most preferably 135° C. to 145° C.; the time duration is preferably 4.5 min to 5.5 min, and more preferably 4.8 min to 5.2 min; the power of hafnium target is preferably 180 W to 185 W, more preferably 181 W to 184 W, and most preferably 182 W to 183 W.

When the deposition method is magnetron sputtering physical vapor deposition, the purity of the platinum target for depositing the platinum layer is preferably 99.999%, and the diameter of the platinum target is preferably 75 mm. In the present disclosure, the conditions for depositing the platinum layer is preferably as follows: the flow rate of argon gas is preferably 39 sccm to 41 sccm, and more preferably 40 sccm; the working pressure for argon plasma is preferably 6.0×10⁻¹ Pa to 8.0×10⁻¹ Pa, more preferably 6.5×10⁻¹ Pa to 7.5×10⁻¹ Pa, and most preferably 6.8×10⁻¹ Pa to 7.3×10⁻¹ Pa; the temperature is preferably 120° C. to 160° C., and more preferably 130° C. to 150° C.; the time duration is preferably 4.5 min to 5.5 min, and more preferably 5 min; the power of platinum target is preferably 180 W to 185 W, and more preferably 182 W to 183 W.

In the present disclosure, the deposition process above is preferably carried out in a commercial magnetron sputtering equipment, which preferably includes three independently controllable magnetron sputtering target sources. The titanium target, platinum target and hafnium target are arranged in the three independently controllable magnetron sputtering target sources, respectively.

The present disclosure further provides an application of the structural coating described in the above technical solution or the structural coating prepared by the method described in the above technical solution in an electric heating element. The present disclosure has no special limitation on the method of the application, and those well known to the skilled in the art may be used.

The structural coating and preparation method and use thereof provided in the present disclosure will be described in detail below in conjunction with examples, but these examples should not be construed as limiting the scope of the present disclosure.

### Example 1

A titanium target with a purity of 99.995% and a diameter of 75 mm, a platinum target with a purity of 99.99% and a diameter of 75 mm and a hafnium target with a purity of 99.99% and a diameter of 75 mm were arranged on three independently controllable magnetron sputtering sources on a commercial magnetron sputtering equipment, respectively.

The surface of a silicon nitride substrate was pretreated, wherein the silicon nitride substrate was etched with argon plasma under a bias voltage of −500 V for 15 min.

A titanium transition layer was deposited on the pretreated surface of the substrate, wherein the flow rate of argon gas was 40 sccm, the working pressure for argon plasma was 6.5×10⁻¹ Pa, the deposition temperature was 150° C., the power of titanium target was 235 W, and the deposition time duration was 15 min, obtaining the titanium transition layer (140 nm).

A hafnium layer was deposited on the surface of the titanium transition layer, wherein the flow rate of argon gas was 40 sccm, the working pressure for argon plasma was 6.5×10⁻¹ Pa, the deposition temperature was 150° C., the power of hafnium target was 185 W, and the deposition time duration was 5 min, obtaining a first hafnium layer (70 nm).

A platinum layer was deposited on the surface of the hafnium layer, wherein the flow rate of argon gas was 40 sccm, the working pressure for argon plasma was 6.5×10⁻¹ Pa, the deposition temperature was 150° C., the power of platinum target was 185 W, and the deposition time duration was 7.5 min, obtaining a first platinum layer (210 nm).

According to the conditions for depositing the first hafnium layer and the first platinum layer, a second hafnium layer (70 nm), a second platinum layer (210 nm), a third hafnium layer (70 nm) and a third platinum layer (210 nm) were deposited on the surface of the first platinum layer in sequence to obtain the structural coating (recorded as Ti/Hf/Pt/Hf/Pt/Hf/Pt, with a total thickness of 980 nm).

FIG. 1 is a schematic view of the cross-section of the structural coating. It may be seen from FIG. 1 that the structural coating includes the titanium transition layer, the first hafnium layer, the first platinum layer, the second hafnium layer, the second platinum layer, the third hafnium layer and the third platinum layer arranged sequentially on the surface of the substrate.

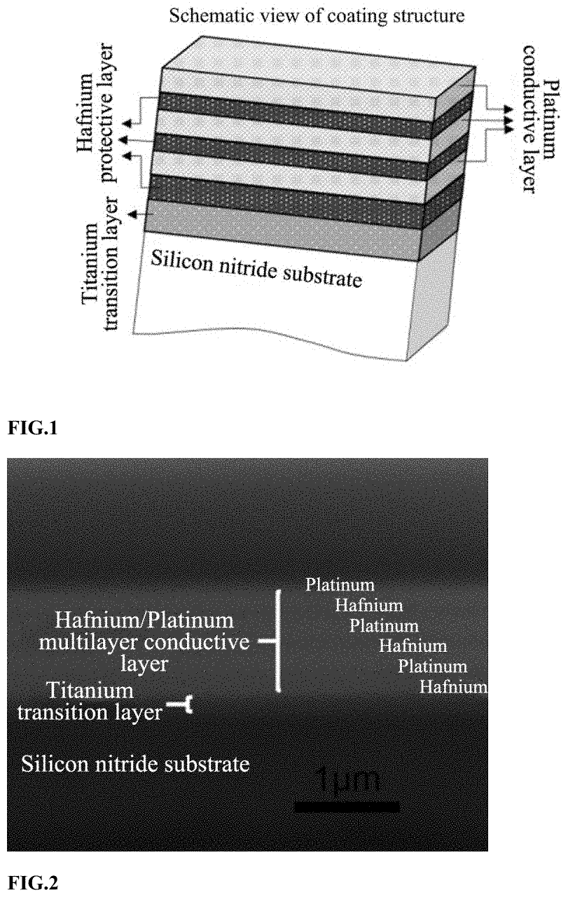

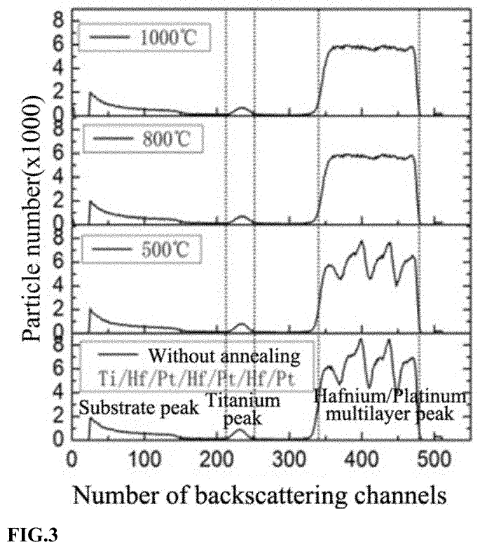

FIG. 2 is a SEM image of the cross-section of the structural coating. It may be seen from FIG. 2 that the respective interfaces between layers in the structural coating are observed, although faintly, limited by the detection means.

The coating sample was heated in a high-vacuum thermal annealing furnace to 500° C., 600° C., 700° C., 800° C., 900° C. and 1000° C., respectively, and was kept for 30 min at the highest heating temperature. The Rutherford backscattering spectrum (RBS) of the coating before and after heating was analyzed using He′ ions with energy of 3 MeV. The testing results are shown in FIG. 3. When the coating sample is heated to 500° C., there is no significant change in the peaks of the hafnium layers and platinum layers and the peak of titanium. When the coating sample is heated to 800° C., the above structure disappears, indicating that diffusion occurs at the interfaces between the hafnium layers and the platinum layers, while there is still no significant change in the peak of titanium. When the coating sample is heated to 1000° C., the spectrum of the structural coating shows no significant difference from that at 800° C., indicating that the above structure inhibits the diffusion of titanium to the platinum layer.

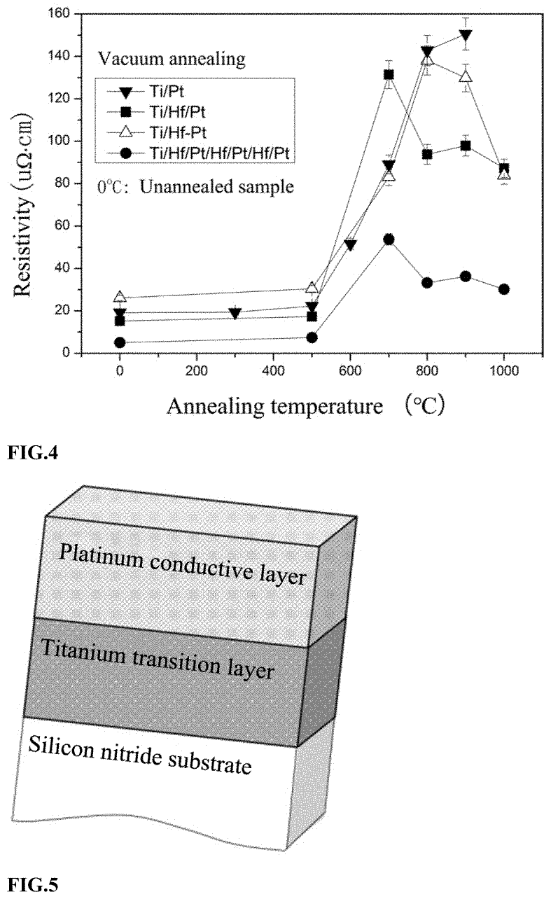

The resistivity of the coating material was measured by a four-probe testing method on a RTS-9 dual-electric four-probe tester, and the average value of three tests was used as the resistivity data. The testing results are shown in FIG. 4. It may be seen from FIG. 4 that the resistivity increases slowly from 6 μΩ·cm to 8 μΩ·cm as the temperature is increased from room temperature to 500° C. When the heat treatment temperature is further increased, the resistivity increases to a maximum value of about 54 μΩ·cm at 700° C. When the heat treatment temperature is further increased, the resistivity begins to decrease to 31 μΩ·cm.

### Comparative Example 1

A titanium target with a purity of 99.995% and a diameter of 75 mm, a platinum target with a purity of 99.99% and a diameter of 75 mm and a hafnium target with a purity of 99.99% and a diameter of 75 mm were arranged on three independently controllable magnetron sputtering sources on a commercial magnetron sputtering equipment, respectively.

The surface of a silicon nitride substrate was pretreated, wherein the silicon nitride substrate was etched with argon plasma under a bias voltage of −500 V for 15 min.

A titanium transition layer was deposited on the pretreated surface of the substrate, wherein the flow rate of argon gas was 40 sccm, the working pressure for argon plasma was 6.5×10⁻¹ Pa, the deposition temperature was 150° C., the power of titanium target was 235 W, and the deposition time duration was 30 min, obtaining the titanium transition layer (280 nm).

A platinum layer was deposited on the surface of the titanium transition layer, wherein the flow rate of argon gas was 40 sccm, the working pressure for argon plasma was 6.5×10⁻¹ Pa, the deposition temperature was 150° C., the power of platinum target was 185 W, and the deposition time duration was 20 min, obtaining the platinum layer (600 nm). A structural coating was obtained (recorded as Ti/Pt).

FIG. 5 is a schematic view of the cross-section of the structural coating. It may be seen from FIG. 5 that the structural coating includes the titanium transition layer and the platinum layer arranged sequentially on the surface of the substrate.

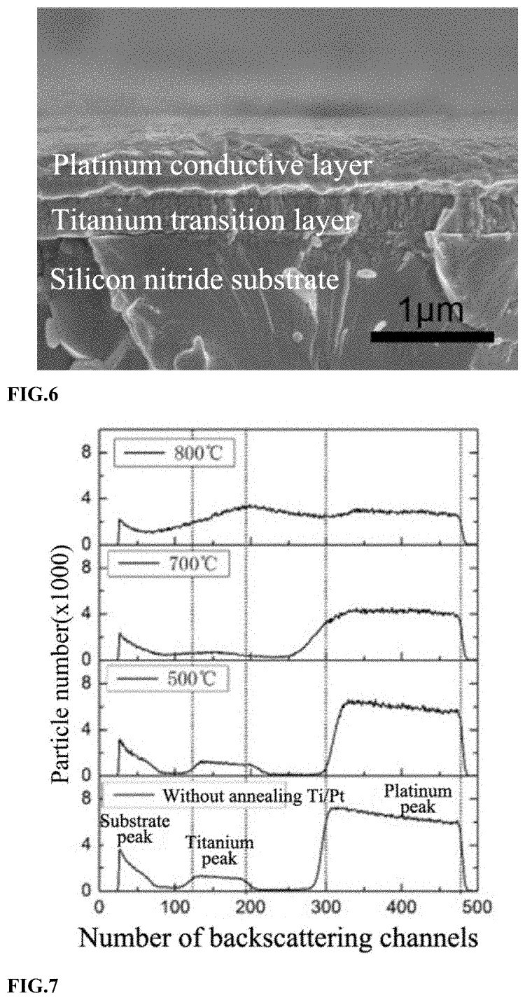

FIG. 6 is a SEM image of the cross-section of the structural coating. It may be seen from FIG. 6 that the respective interfaces between layers in the structural coating are observed clearly.

The coating sample was heated in a high-vacuum thermal annealing furnace to 500° C., 600° C., 700° C., 800° C., 900° C. and 1000° C., respectively, and was kept for 30 min at the highest heating temperature. The Rutherford backscattering spectrum (RBS) of the coating before and after heating was analyzed using He⁴⁺ ions with energy of 3 MeV. The testing results are shown in FIG. 7. When the coating sample is heated to 700° C. or higher, the backscattering peaks of platinum and titanium change significantly, and the diffusion of titanium into the platinum layer occurs.

The resistivity of the coating material was measured by a four-probe testing method on a RTS-9 dual-electric four-probe tester, and the average value of three tests was used as the resistivity data. The testing results are shown in FIG. 4. It may be seen from FIG. 4 that the resistivity is 20 μΩ·m at room temperature, and shows no significant increase when being heated to 500° C. When being heated to 700° C., the resistivity increases to 89 μΩ cm. When the heat treatment temperature is further increased to 800° C., the resistivity increases to 143 μΩ cm. When being continuously heated to 900° C., the resistivity continues to increase.

### Comparative Example 2

A titanium target with a purity of 99.995% and a diameter of 75 mm, a platinum target with a purity of 99.99% and a diameter of 75 mm and a hafnium target with a purity of 99.99% and a diameter of 75 mm were arranged on three independently controllable magnetron sputtering sources on a commercial magnetron sputtering equipment, respectively.

The surface of a silicon nitride substrate was pretreated, wherein the silicon nitride substrate was etched with argon plasma under a bias voltage of −500 V for 15 min to remove the natural oxidation layer and impurity contamination layer from the substrate surface.

A titanium transition layer was deposited on the pretreated surface of the substrate, wherein the flow rate of argon gas was 40 sccm, the working pressure for argon plasma was 6.5×10⁻¹ Pa, the deposition temperature was 150° C., the power of titanium target was 235 W, and the deposition time duration was 15 min, obtaining the titanium transition layer (140 nm).

A hafnium layer was deposited on the surface of the titanium transition layer, wherein the flow rate of argon gas was 40 sccm, the working pressure for argon plasma was 6.5×10⁻¹ Pa, the deposition temperature was 150° C., the power of hafnium target was 155 W, and the deposition time duration was 20 min, obtaining the hafnium layer (200 nm).

A platinum layer was deposited on the surface of the hafnium layer, wherein the flow rate of argon gas was 40 sccm, the working pressure for argon plasma was 6.5×10⁻¹ Pa, the deposition temperature was 150° C., the power of platinum target was 185 W, and the deposition time duration was 10 min, obtaining the platinum layer (280 nm). A structural coating was obtained (recorded as Ti/Hf/Pt, with a total thickness of 620 nm).

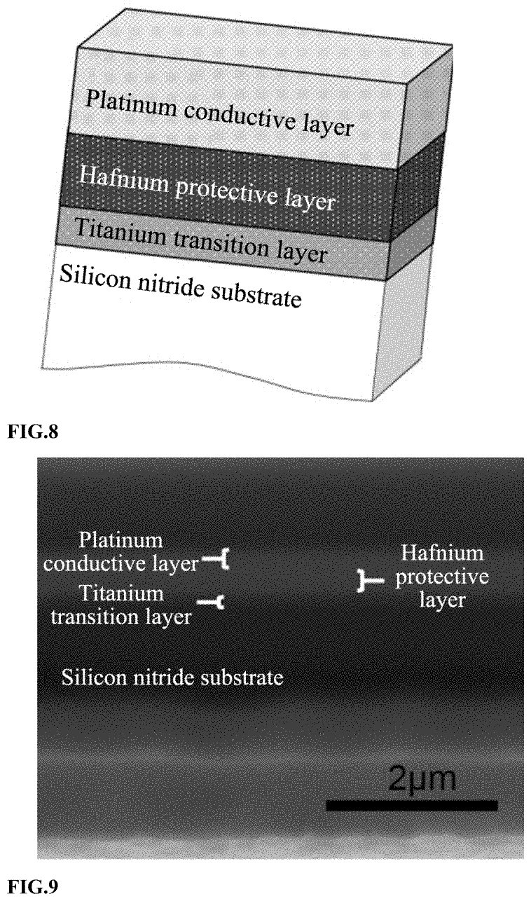

FIG. 8 is a schematic view of the cross-section of the structural coating. It may be seen from FIG. 8 that the structural coating includes the titanium transition layer, the hafnium layer and the platinum layer arranged sequentially on the surface of the substrate.

FIG. 9 is a SEM image of the cross-section of the structural coating. It may be seen from FIG. 9 that the respective interfaces between layers in the structural coating are observed clearly.

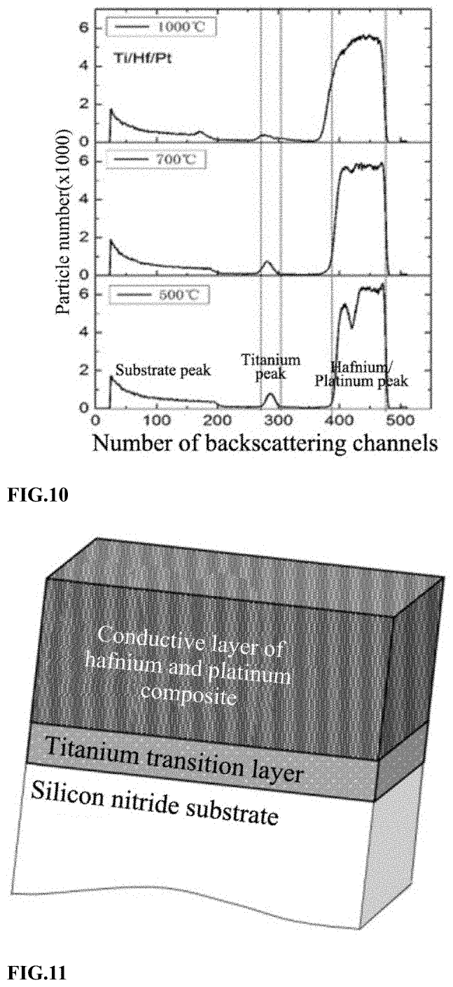

The coating sample was heated in a high-vacuum thermal annealing furnace to 500° C., 600° C., 700° C., 800° C., 900° C. and 1000° C., respectively, and was kept for 30 min at the highest heating temperature. The Rutherford backscattering spectrum (RBS) of the coating before and after heating was analyzed using He′ ions with energy of 3 MeV. The testing results are shown in FIG. 10. When the coating sample is heated to 700° C. or higher, the backscattering peaks of hafnium/platinum and titanium change significantly, and the diffusion of titanium into the Hf/Pt layer occurs.

The resistivity of the coating material was measured by a four-probe testing method on a RTS-9 dual-electric four-probe tester, and the average value of three tests was used as the resistivity data. The testing results are shown in FIG. 4. It may be seen from FIG. 4 that the resistivity increases slowly from 15 μΩ·m to 17 μΩ·cm when the temperature is increased from room temperature to 500° C. When being heated to 700° C., the resistivity increases to 130 μΩ cm. When being further heated, the resistivity decreases to 90 μΩ cm and keeps constant substantially.

### Comparative Example 3

A titanium target with a purity of 99.995% and a diameter of 75 mm, a platinum target with a purity of 99.99% and a diameter of 75 mm and a hafnium target with a purity of 99.99% and a diameter of 75 mm were arranged on three independently controllable magnetron sputtering sources on a commercial magnetron sputtering equipment, respectively.

The surface of a silicon nitride substrate was pretreated, wherein the silicon nitride substrate was etched with argon plasma under a bias voltage of −500 V for 15 min.

A titanium transition layer was deposited on the pretreated surface of the substrate, wherein the flow rate of argon gas was 40 sccm, the working pressure for argon plasma was 6.5×10⁻¹ Pa, the deposition temperature was 150° C., the power of titanium target was 235 W, and the deposition time duration was 15 min, obtaining the titanium transition layer (140 nm).

A layer of hafnium and platinum composite was deposited on the surface of the titanium transition layer, wherein the flow rate of argon gas was 40 sccm, the working pressure for argon plasma was 6.5×10⁻¹ Pa, the deposition temperature was 150° C., the deposition time duration was 15 min, the power of hafnium target was 185 W, and the power of platinum target was 50 W, obtaining the layer of hafnium and platinum composite (650 nm). A structural coating was obtained (recorded as Ti/Hf—Pt, with a total thickness of 790 nm).

FIG. 11 is a schematic view of the cross-section of the structural coating. It may be seen from FIG. 11 that the structural coating includes the titanium transition layer and the layer of hafnium and platinum composite arranged sequentially on the surface of the substrate.

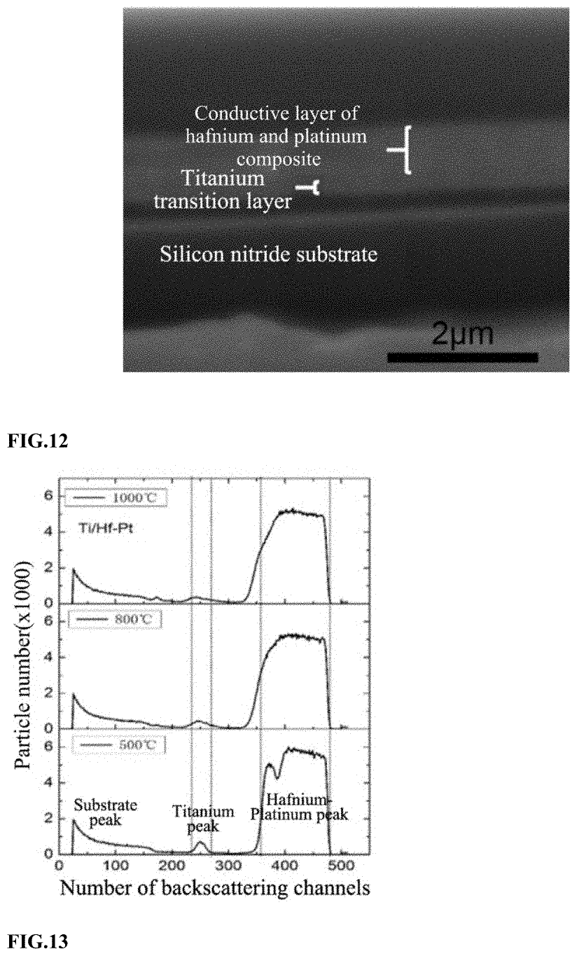

FIG. 12 is a SEM image of the cross-section of the structural coating. It may be seen from FIG. 12 that the respective interfaces between layers in the structural coating are observed clearly.

The coating sample was heated in a high-vacuum thermal annealing furnace to 500° C., 600° C., 700° C., 800° C., 900° C. and 1000° C., respectively, and was kept for 30 min at the highest heating temperature. The Rutherford backscattering spectrum (RBS) of the coating before and after heating was analyzed using He′ ions with energy of 3 MeV. The testing results are shown in FIG. 13. When the coating sample is heated to 800° C. or higher, the backscattering peaks of hafnium-platinum and titanium change significantly, and the diffusion of titanium into the Hf—Pt layer occurs.

The resistivity of the coating material was measured by a four-probe testing method on a RTS-9 dual-electric four-probe tester, and the average value of three tests was used as the resistivity data. The testing results are shown in FIG. 4. It may be seen from FIG. 4 that when the temperature is increased from room temperature to 500° C., the resistivity increases slowly from 26 μΩ cm to 30 μΩ cm. When being heated to 800° C., the resistivity increases to 138 μΩ cm. When being further heated, the resistivity decreases to 84 μΩ cm and keeps constant substantially.

In conclusion, based on above, the structural coating of the present disclosure has a relatively high thermal stability.

The above are only preferred embodiments of the present disclosure. It should be noted that for those skilled in the art, several improvements and modifications may be made without departing from the principle of the disclosure. These improvements and modifications should also be regarded as falling within the protection scope of the present disclosure.

1. A structural coating, comprising a titanium transition layer and platinum-hafnium composite structure layers laminated sequentially on a surface of a substrate; the number of the platinum-hafnium composite structure layer is ≥3;
the platinum-hafnium composite structure layer comprises a hafnium layer and a platinum layer laminated in sequence.

2. The structural coating according to claim 1, wherein the structural coating has a total thickness of 900 nm to 2000 nm.

3. The structural coating according to claim 1, wherein the titanium transition layer has a thickness of 140 nm to 300 nm.

4. The structural coating according to claim 1, wherein a thickness ratio of the platinum layer to the hafnium layer is (20-22):(7-10).

5. A method for preparing the structural coating according to claim 1, comprising:
preparing a titanium transition layer and platinum-hafnium composite structure layers sequentially on a surface of a substrate to obtain the structural coating;
a process of preparing the platinum-hafnium composite structure layers comprises depositing a hafnium layer and a platinum layer sequentially and repeatedly on a surface of the titanium transition layer, and the deposition of the hafnium layer and the platinum layer is repeated for ≥3 times.

6. The method according to claim 5, wherein conditions for depositing the titanium transition layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 14 min to 16 min; a power of Ti target is 220 W to 250 W.

7. The method according to claim 5, wherein conditions for depositing the hafnium layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 4.5 min to 5.5 min; a power of hafnium target is 180 W to 185 W.

8. The method according to claim 5, wherein conditions for depositing the platinum layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 7 min to 8 min; a power of platinum target is 180 W to 185 W.

9. A method for preparing an electric heating element, using the structural coating according to claim 1.

10. The structural coating according to claim 2, wherein a thickness ratio of the platinum layer to the hafnium layer is (20-22):(7-10).

11. The structural coating according to claim 3, wherein a thickness ratio of the platinum layer to the hafnium layer is (20-22):(7-10).

12. The method according to claim 5, wherein the structural coating has a total thickness of 900 nm to 2000 nm.

13. The method according to claim 5, wherein the titanium transition layer has a thickness of 140 nm to 300 nm.

14. The method according to claim 5, wherein a thickness ratio of the platinum layer to the hafnium layer is (20-22):(7-10).

15. The method according to claim 12, wherein a thickness ratio of the platinum layer to the hafnium layer is (20-22):(7-10).

16. The method according to claim 13, wherein a thickness ratio of the platinum layer to the hafnium layer is (20-22):(7-10).

17. The method according to claim 9, wherein the structural coating has a total thickness of 900 nm to 2000 nm.

18. The method according to claim 9, wherein a thickness ratio of the platinum layer to the hafnium layer is (20-22):(7-10).

19. A method for preparing an electric heating element, using the structural coating prepared by the method according to claim 5.

20. The method according to claim 19, wherein conditions for depositing the hafnium layer are as follows: a flow rate of argon gas is 39 sccm to 41 sccm; a working pressure for argon plasma is 6.0×10⁻¹ Pa to 8.0×10⁻¹ Pa; a temperature is 120° C. to 160° C.; a time duration is 4.5 min to 5.5 min; a power of hafnium target is 180 W to 185 W.
